(19) United States
(12) Patent Application Publication
(10) Pub. No.: US 2023/0127057 A1
(43) Pub. Date: Apr. 27, 2023

(54) PIXELATED FILTER

(71) Applicant: Commissariat à l'Énergie Atomique et aux Énergies Alternatives, Paris (FR)

(72) Inventors: Sébastien Verdet, Grenoble Cedex 9 (FR); Cédric Giroud-Garampon, Grenoble Cedex 9 (FR)

(73) Assignee: Commissariat à l'Énergie Atomique et aux Énergies Alternatives, Paris (FR)

(21) Appl. No.: 17/972,937

(22) Filed: Oct. 25, 2022

(30) Foreign Application Priority Data
Oct. 27, 2021 (FR) 2111421

(51) Int. Cl. H01L 27/146; G02B 5/28

(52) U.S. Cl. CPC H01L 27/1462; G02B 5/28; H01L 27/14649; H01L 27/14685

(57) ABSTRACT

A pixelated filter wherein each pixel of the pixelated filter includes an interference filter including a stack of layers, and one or a plurality of waveguides each crossing all or part of the layers of said interference filter. In each pixel of the pixelated filter, the waveguide are configured to guide at least one optical mode and so that an evanescent portion of said at least one guided mode is filtered by the interference filter of the pixel.

### CROSS REFERENCE TO RELATED APPLICATION

This application claims priority to French application number 2111421, filed Oct. 27, 2022. The contents of which is incorporated herein by reference in its entirety.

### TECHNICAL BACKGROUND

The present disclosure generally concerns pixelated filters, methods of manufacturing these pixelated filters, and devices comprising such pixelated filters.

### PRIOR ART

Many known devices comprise a plurality of photosensitive elements and a structure or layer comprising a plurality of pixels, each pixel comprising an interference filter. The structure comprising the plurality of filters is called pixelated filter, and each pixel of the pixelated filter is called filter pixel, or more simply pixel.

In these known devices, the pixelated filter rests on the plurality of photosensitive elements, so that each photosensitive element is topped with a pixel of the pixelated filter, and thus with an interference filter. One or a plurality of layers may be interposed between the photosensitive elements and the pixelated filter and/or one or a plurality of layers may rest on the pixelated filter.

In these known devices, also called light sensors, the incident light received by the sensor and intended to be transmitted to a given photosensitive element first has to cross the filter pixel topping this photosensitive element and, if they are present, the layers arranged above and/or under the filter pixel, before reaching this photosensitive element. Part of this incident light may reach a neighboring photosensitive element. This results in a loss of useful signal of the photosensitive element which was intended to receive this incident light towards its neighboring photosensitive elements. This phenomenon is called crosstalk. The crosstalk increase results in a loss of resolution.

The crosstalk is all the more significant as the dimensions and the pitch of the photosensitive elements decrease and/or as the total thickness of the layers crossed by the incident light before reaching the photosensitive elements increases. As an example, the total thickness of the layers crossed by the light increases when the number of layers of the interference filters increases to improve the filtering characteristics of the filters and/or the range of angle of incidence of light over which these filters have desired filtering characteristics.

### SUMMARY OF THE INVENTION

There is a need to overcome all or part of the disadvantages of known devices comprising a pixelated filter.

An embodiment overcomes all or part of the disadvantages of known pixelated filters comprising filter pixels, each comprising an interference filter.

An embodiment provides a pixelated filter wherein each pixel of the pixelated filter comprises an interference filter comprising a stack of layers, and a plurality of waveguides, each crossing all or part of the layers of said interference filter. In each pixel of the pixelated filter, the waveguides are configured to guide at least one optical mode and so that an evanescent portion of said at least one guided mode is filtered by the interference filter of said pixel.

According to an embodiment, the waveguides of each two neighboring pixels of the pixelated filter are configured so that the guided optical modes of the two pixels do not couple with one another.

According to an embodiment, the pixelated filter is configured to rest on a surface of a plurality of photoactive elements so that each photoactive element is in front of a pixel of the pixelated filter.

According to an embodiment, at least two pixels of the pixelated filter are different.

According to an embodiment, in each pixel of the pixelated filter, the layers crossed by the waveguides are dielectric layers, and each waveguide is made of one or a plurality of materials, each having a refraction index having its real part greater than the real part of the refraction index of each of the dielectric layers crossed by said waveguide.

According to an embodiment, each waveguide has a substantially constant cross-section along its entire length.

According to an embodiment, the waveguides of one or a plurality of pixels of the pixelated filter have different lengths.

According to an embodiment, in each pixel of the pixelated filter, the waveguides of said pixel are made of the same materials and have a same cross-section.

According to an embodiment, in each pixel of the pixelated filter, the waveguides of said pixel are organized in a network.

According to an embodiment, in at least one of the pixels of the pixelated filter, the network of waveguides of said pixel is symmetrical with respect to a central axis of said pixel and the waveguides of the network each have a same cross-section, symmetrical with respect to a central longitudinal axis of said waveguide.

Another embodiment provides a device comprising a plurality of photoactive elements and a pixelated filter such as described hereabove, wherein the pixelated filter rests on the plurality of photoactive elements so that each photoactive element is in front of a pixel of the pixelated filter.

Another embodiment provides a method of manufacturing a pixelated filter such as described hereabove, comprising the following steps of:
a) providing a structure comprising, at each location of a pixel of the pixelated filter, a stack of all or part of the layers of an interference filter of said pixel;
b) for each pixel of the pixelated filter, forming a mask and a plurality of openings in said mask;
c) for each pixel of the pixelated filter, etching a trench from each opening, the trench crossing all or part of the layers of the interference filter of said pixel; and
d) filling each trench to form a waveguide therein,
wherein, in each pixel of the pixelated filter, the waveguides are configured to guide at least one optical mode and so that an evanescent portion of said at least one guided mode is filtered by the interference filter of said pixel.

According to an embodiment, at step a), for each pixel, the stack comprises only part of the layers of the interference filter of said pixel, the method comprising after step d), for each pixel, the forming of the other part of the layers of the interference filter of said pixel.

Another embodiment provides a device manufacturing method comprising:
manufacturing, on a support, a pixelated filter by implementing the above-described pixelated filter manufacturing method;
transferring the pixelated filter and the support onto a plurality of photoactive elements so that each photoactive element is in front of a pixel of the pixelated filter and that the pixelated filter is interposed between the plurality of photoactive elements and the support.

According to an embodiment, the method further comprises, after the transfer step:
a step of thinning of said support, said support being made of a material transparent to the wavelengths transmitted by each of the interference filters; or
a step of removal of said support.

Another embodiment provides a method of manufacturing a device comprising the manufacturing, on a plurality of photoactive elements, of a pixelated filter by implementing the above-described pixelated filter manufacturing method, so that each photoactive element is in front of a pixel of the pixelated filter.

According to an embodiment, each of the device manufacturing methods described hereabove further comprises, for each pixel of the pixelated filter, a step of determination of an arrangement of the waveguides of said pixel with respect to one another and of the dimensions of the cross-sections of said waveguides of said pixel maximizing an optical power of an evanescent portion of a super optical mode guided by the waveguides of said pixel.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 is a simplified cross-section view of an example of embodiment of a light sensor;

FIG. 2 is a simplified top view of a pixelated filter of the sensor of FIG. 1;

FIG. 3 illustrates with curves simulation results comparing a pixel of the pixelated filter of FIGS. 1 and 2 with a reference filter pixel;

FIG. 4 illustrates with curves other simulation results comparing a pixel of the pixelated filter of FIGS. 1 and 2 with a reference filter pixel;

FIG. 5 is a simplified cross-section view of a pixel of the pixelated filter of the sensor of FIGS. 1 and 2 according to an alternative embodiment;

FIG. 6 is a simplified cross-section view of two pixels of the pixelated filter of the sensor of FIGS. 1 and 2 according to another alternative embodiment;

FIG. 7 is a simplified cross-section view of a pixel of the pixelated filter of the sensor of FIGS. 1 and 2 according to still another alternative embodiment;

FIG. 8 is a simplified cross-section view of a pixel of the pixelated filter of the sensor of FIGS. 1 and 2 according to still another alternative embodiment;

FIG. 9 is a simplified cross-section view of a pixel of the pixelated filter of the sensor of FIGS. 1 and 2 according to still another alternative embodiment;

FIG. 10 illustrates in cross-section views an embodiment of a pixelated filter manufacturing method;

FIG. 11 illustrates in cross-section views an alternative embodiment of the method of FIG. 9;

FIG. 12 illustrates in cross-section views an alternative embodiment of the method of FIG. 11;

FIG. 13 illustrates in cross-section views another embodiment of a pixelated filter manufacturing method; and

FIG. 14 illustrates in a cross-section view a next step of the method of FIG. 13.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following disclosure, unless otherwise specified, when reference is made to absolute positional qualifiers, such as the terms “front”, “back”, “top”, “bottom”, “left”, “right”, etc., or to relative positional qualifiers, such as the terms “above”, “below”, “upper”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

Unless specified otherwise, in the rest of the disclosure, a first layer rests on a second layer or covers the second layer means either that the first layer directly rests on the second layer or, in other words, that the first layer is arranged on top of and in contact with the second layer, or that the first layer indirectly rests on the second layer, or, in other words, that one or a plurality of layers may be interposed between the first and second layers.

The present disclosure provides a pixelated filter comprising a plurality of filter pixels, where each pixel comprises an interference filter comprising a stack of layers, and one or a plurality of waveguides, each crossing all or part of the layers of the interference filter. In each filter pixel, the waveguide(s) of the pixel are configured to guide one or a plurality of optical modes and so that an evanescent portion these guided modes is filtered by the interference filter of the pixel. In other words, in each filter pixel, the waveguides are configured so that an evanescent portion of the optical modes guided by this or these waveguides interacts with the layers of the interference filter that this or these guides cross. The interaction of the evanescent portion of the guided modes with the layers of the interference filters enables for the light guided by the waveguides to be filtered by the filters.

In addition to the fact that the waveguides enable to improve the guiding of light all the way to a corresponding photosensitive element, and thus to decrease the crosstalk between photosensitive elements, this enables to improve the quality of the filtering for each filter pixel, that is, for example, to increase the transmission of the filter pixel in its passband and/or the rejection of the filter pixel out of its passband, and/or to increase the extension of the range of angle of incidence of light where the filter pixel is insensitive, or substantially insensitive, to the angle of incidence of light.

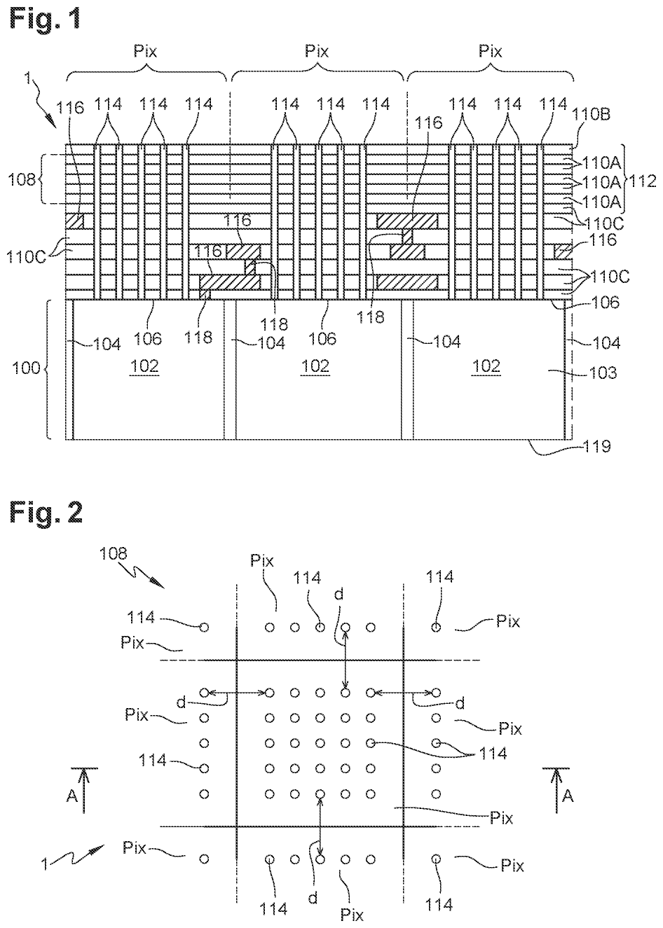

FIG. 1 is a simplified view illustrating an example of embodiment of a light sensor 1. FIG. 2 is a top view of an example of embodiment of a pixelated filter 108 of sensor 1, FIG. 1 being taken in plane AA of FIG. 2.

Sensor 1 comprises a plurality 100 of photosensitive elements 102, for example arranged in an array of rows and columns of photosensitive elements 102. In FIG. 1, only three photosensitive elements 102 of sensor 1 are shown. In practice, sensor 1 for example comprises several hundreds or several thousands of photosensitive elements 102.

Photosensitive elements 102 are formed, that is, arranged, in a layer 103, for example a semiconductor substrate.

As an example, each photosensitive element 102 is a photodiode formed in a semiconductor substrate 103. As an example, substrate 103 is made of silicon, and sensor 1 is configured to operate with light having wavelengths in the visible range and near infrared, for example, wavelengths in the range from 400 to 1,000 nm. As an example, each photodiode 102 is laterally delimited by vertical insulation structures 104, for example, deep trench insulations (DTI) or capacitive deep trench insulations (CDTI, “Capacitive DTI”). Structures 104 electrically insulate photodiodes 102 from one another. Structures 104 may take part in optically insulating photodiodes 102 from one another.

In other examples, not illustrated, each photosensitive element 102 is a bolometer or an infrared photodetector made of InSb and/or of HgCdTe (MCT). Those skilled in the art will be capable of providing other examples of photosensitive elements 102.

Each photosensitive element 102 comprises a surface 106 configured to receive light. In the example of FIG. 1, the surface 106 of each photosensitive element 100 corresponds to a portion of the surface 106 (upper surface in FIG. 1) of substrate 103 comprising photosensitive elements 102.

Sensor 1 further comprises pixelated filter 108. The pixelated filter comprises a plurality of filter pixels Pix. Pixelated filter 108 rests on the array 100 of elements 102, that is, on substrate 103, so that each photosensitive element 102 is topped with or is in front of or is coated with a filter pixel Pix. Preferably, each element 102 is topped with a single pixel Pix, and each pixel Pix rests on a single photosensitive element 102.

Each pixel Pix comprises a stack of layers 110A having an interference filter 112 defined therein. In other words, each pixel Pix comprises a stack of layers 110A, at least some of which form interference filter 112. In the example of FIG. 1, each filter pixel Pix only comprises the layers 110A of its filter 112 or, in other words, only comprises its filter 112.

The layers 110A of each filter 112 are stacked on one another, in contact two by two. In the example of FIG. 1, each filter 112 is an interferometric filter, and the layers 110a of each filter 112 are dielectric layers. As an example, the layers 110A of each filter 112 comprise layers 110A made of a first dielectric material and layers 110A made of a second dielectric material, the layers of the first material being alternated with the layers of the second material.

In the example of FIG. 1, each filter 112 comprises the same layers 110A or, in other words, the filters 112 of pixels Pix are all identical.

As an example, the filter 112 of each pixel Pix is a low-pass filter configured to block infrared light, that is, for example, light having wavelengths greater than 900 nm. However, in other examples, filter 112 may be a bandpass filter configured to let through blue, red, or green visible light only, or any other type of interferometric filter.

Each pixel Pix comprises at least one waveguide 114, and, more particularly, a plurality of waveguides 114 in the example of FIGS. 1 and 2.

For example, as illustrated in FIG. 2, each pixel Pix comprises twenty-five waveguides 114. To avoid overloading FIG. 2, a single pixel Pix of filter 108 is entirely shown in FIG. 2, and a single waveguide 114 per pixel Pix is referenced in FIG. 2.

In the example illustrated in FIG. 2, the waveguides 114 of each pixel Pix are organized in an array network, that is, an array of rows and of columns of waveguides 114.

In other examples, not illustrated, the waveguides 114 of pixel Pix form a network where the waveguides 114 are arranged with respect to one another in a triangle or in a quincunx. In still other examples, not illustrated, the waveguides 114 of pixel Pix are not organized in a network.

As an example, the organization or arrangement of waveguides 114 with respect to one another is the same in each pixel Pix of pixelated filter 108. In other examples, this organization may be different between two pixels Pix.

In each pixel Pix, each waveguide 114 of pixel Pix crosses all or part, that is, at least some, of the layers 110A of the filter 112 of pixel Pix. Preferably, in each pixel Pix, each waveguide 114 crosses all the dielectric layers 110A of the filter 112 of pixel Pix.

It is here considered that a waveguide 114 crosses a layer, for example, when it crosses the layer across its entire thickness, substantially orthogonal to the layer. Thus, since layers 110A each extend substantially parallel to surface 106, waveguides 114 extend longitudinally in a direction orthogonal to surface 106.

In each pixel Pix of pixelated filter 108, waveguide(s) 114 are configured to guide one or a plurality of optical modes and so that an evanescent portion of these guided modes is filtered by the interference filter 112 of pixel Pix.

Pixelated filter 108 may be coated with one or a plurality of dielectric layers 110B, for example with a single dielectric layer 110B as shown in FIG. 1. Layer(s) 110B are for example antireflection layers and/or passivation layers.

According to an embodiment where pixelated filter 108 is coated with one or a plurality of layers 110B, waveguides 114 may extend through all or part of these layers 110B or, in other words, may cross at least some of these layers 110B. For example, in FIG. 1, waveguides 114 cross all layers 110B.

According to an alternative embodiment not illustrated where pixelated filter 108 is coated with one or a plurality of layers 110B, waveguides 114 cross no layer 110B.

Pixelated filter 108 may rest on a dielectric layer 110C or a stack of dielectric layers 110C as shown in FIG. 1. These layers 110C for example comprise antireflection layers and/or passivation layers.

When pixelated filter 108 rests on layers 110C, an interconnection structure may be embedded in layers 110C as shown in FIG. 1, the sensor is then said to have a front side illumination (FSI). As an example, the interconnection structure comprises portions of conductive layers 116 insulated from one another by layers 110C and electrically connected to one another by conductive vias crossing layers 110C.

According to an embodiment where pixelated filter 108 rests on one or a plurality of layers 110C, waveguides 114 may extend through all or part of these layers 110C, or, in other words, may cross at least some of these layers 110C. For example, waveguides 114 cross all layers 110C, all the way to the surface 106 of layer 103 comprising photosensitive elements 102.

According to an alternative embodiment not illustrated where pixelated filter 108 rests on one or a plurality of layers 110C, waveguides 114 cross no layer 110C.

In an embodiment where filter 108 rests on layers 110C, an interconnection structure 116, 118 is embedded in layers 110C, and waveguides 114 cross at least some of layers 110C, preferably, waveguides 114 do not cross the portions of layers 116. Further, preferably, each waveguide 114 is arranged sufficiently far from the portions of layers 116, for example, at a distance greater than or equal to one quarter of the smallest wavelength of the light guided by waveguide 114, so that these portions of layers 116 do not disturb the propagation of light by the waveguide.

According to an alternative embodiment, not illustrated, sensor 1 comprises no layer 110C or interconnection structure 116, 118 embedded in these layers 110C. The interconnection structure of sensor 1 is then embedded in insulating layers resting on a surface 119 of substrate 103, surface 119 being opposite to surface 106. Such a sensor 1 is said to have a back side illumination (BSI).

According to an embodiment, in each pixel Pix, each waveguide 114 is made of one or a plurality of materials, each having an optical index having its real part greater than or equal to, preferably greater than, the real part of the optical index of the material of each of the layers 110A, 110B, 110C crossed by this waveguide 114. In each pixel Pix, one or a plurality of optical modes or one or a plurality of super optical modes are then guided by the waveguides 114 of pixel Pix. Further, an evanescent portion of these guided modes is then present in the layers 110A crossed by waveguides 114 and interacts with these layers 110A, whereby the evanescent portion of the guided modes, and, more generally, the actual guided modes, are filtered by the filter 112 of pixel Pix.

According to an embodiment, for each pixel Pix, waveguides 114 are identical to one another, that is, for example, they have the same length and have their ends arranged at the same levels, they are made of the same materials, and they have the same dimensions. The manufacturing of these waveguides is then simpler to implement. More particularly, in the example of FIG. 1, all the guides 114 of all pixels Pix are identical to one another.

According to an embodiment, each waveguide 114 has a substantially constant cross-section along its entire length, that is, a cross-section which is aimed at being constant but which, in practice, may have dimensions which vary due to the etching methods used on manufacturing of waveguides 114. Waveguides 114 each having a substantially constant cross-section are simpler to manufacture. In the example of FIG. 1, all the waveguides 114 of all pixels Pix have the same cross-section.

According to an embodiment, each waveguide 114 of a pixel has a cross-section having a symmetry of revolution with respect to an axis parallel to the longitudinal direction of the waveguide. As an example, the cross-section of waveguide 114 then has the shape of a disk of circular contour. This symmetry enables the propagation of light by each waveguide 114 of a pixel to be independent from the polarization of light. Preferably, the waveguides 114 of pixel Pix are then organized in an array having a symmetry of revolution with respect to a central axis of pixel Pix, that is, an axis parallel to waveguides 114 running through the center of pixel Pix. Thus, the propagation of the optical mode(s) guided by the waveguides 114 of pixel Pix is independent from the polarization of light.

According to another embodiment, each waveguide 114 of a pixel Pix has a cross-section having no symmetry of revolution with respect to an axis parallel to the longitudinal direction of waveguide 114, which enables the propagation of the light guided by waveguide 114 to depend on the polarization of light. Preferably, this dependency between the polarization of light and the way in which the light is guided in pixel Pix by its waveguides 114 is exacerbated by providing for the waveguides 114 of pixel Pix not to be arranged symmetrically with respect to a central axis of pixel Pix.

According to an embodiment, for each two neighboring pixels Pix of pixelated filter 108, a distance d (FIG. 2) between each waveguide 114 of one of the two neighboring pixels Pix and each waveguide 114 of the other of these two pixels Pix is greater than or equal to λmax/nmin, with λmax the largest of the wavelengths transmitted by the filters 112 of these two neighboring pixels Pix and nmin the smallest of the real parts of the optical indexes of the dielectric layers 110A, 110B, and 110C crossed by the waveguides 114 of these two neighboring pixels Pix. This enables to avoid for the optical modes guided by the waveguides 114 of one of these two neighboring pixels Pix to couple with the optical modes guided by the waveguides 114 of the other of these two neighboring pixels Pix, which would cause crosstalk between these two pixels.

Although this is not illustrated in FIGS. 1 and 2, sensor 1 may comprise lenses or microlenses and/or resin color filters resting on pixelated filter 108. For example, at least one pixel Pix may be topped with a resin color filter and/or with a microlens configured to focus light into the photosensitive element 102 having this pixel Pix resting thereon.

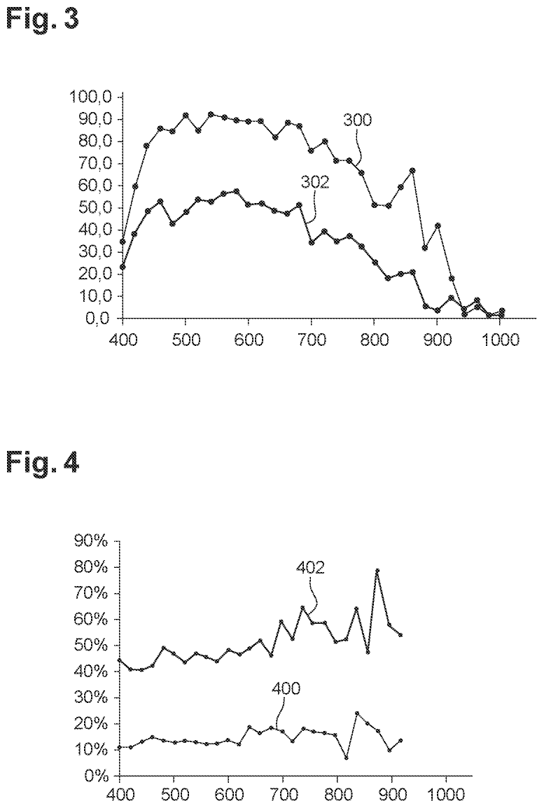

FIG. 3 illustrates in curves 300 and 302 simulation results comparing a filter pixel Pix such as described hereabove with a reference filter pixel. More particularly, curve 300 illustrates the variation of the rate of light transmission by pixel Pix (in percentage and in ordinates) according to the wavelength (in abscissas and in nm), curve 302 illustrating the rate of light transmission by the reference filter pixel according to the wavelength.

FIG. 4 illustrates in curves 400 and 402 the variation of the crosstalk (in percentage and in ordinates) according to the wavelength (in nm and in abscissas), respectively for a pixel Pix of curve 300 and of the reference filter pixel of curve 302.

In FIG. 4, to estimate the crosstalk of pixel Pix (curve 400), four identical pixels Pix are arranged in a square of two pixels Pix by two pixels Pix, three of the four pixels Pix are masked, for example by a tungsten layer, and a microlens if arranged on the unmasked pixel Pix. The four pixels Pix are arranged on four corresponding photosensitive elements 102 (FIG. 1). The crosstalk then corresponds to the ratio of the quantity of light received by the three photosensitive elements 102 topped with the masked pixels Pix to the total quantity of light received by the four photosensitive elements 102. The crosstalk for the reference pixel (curve 402) is obtained similarly, by replacing filter pixels Pix with reference filter pixels.

The curves of FIGS. 3 and 4 have been obtained by a finite different time domain (FDTD) calculation, in this example with an angle of incidence of light on the filter pixels equal to 10°.

In the example of FIGS. 3 and 4, a filter pixel Pix having as a filter 112 a low-pass filter having a cutoff wavelength equal to approximately 940 nm is considered. Pixel Pix only comprises its filter 112, the latter being formed of 32 dielectric layers 110A by alternating a SiN layer 110A and a SiO2 layer 110A. Each layer 110A has a thickness of approximately 100 nm. Waveguides 114 are made of Ta2O5 and cross all the layers 110A of filter 112. Pixel Pix has, in top view, a square surface with a 1.4-μm side length. Pixel Pix comprises 25 waveguides 114 having a disk-shaped cross-section with a 100-nm diameter, distributed in an array of 5 rows and 5 columns with a 160-nm pitch. In this example, the reference pixel is similar to pixel Pix, with the difference that it only comprises 16 layers and that it comprises no waveguide 114. Like pixel Pix, the reference pixel is coated with a microlens.

FIG. 3 shows that the pixel Pix of curve 300 has a better transmission in its passband and a better rejection outside of its passband than the reference pixel of curve 302. In particular, in the passband of the filters 112 of pixel Pix and of the reference pixel, for example between 400 and 900 nm, the transmission rate of pixel Pix is improved by at least 60% with respect to that of the reference pixel and is, for example in average increased by 110% over this wavelength range. Further, the rejection rate of pixel Pix is increased by 260% at 940 nm with respect to that of the reference pixel.

One could expect that the increase in the number of layers in pixel Pix with respect to the reference pixel causes an increase in the crosstalk of pixel Pix with respect to the reference pixel. However, FIG. 4 shows, conversely, that the crosstalk is decreased for pixel Pix with respect to that of the reference pixel. In particular, in the example of FIG. 4, the crosstalk of pixel Pix is decreased, over the wavelength range from 400 to 900 nm, by a factor 3.75 in average.

Further, although this is not illustrated in a drawing, the inventors have observed that results similar to what is described hereabove in relation with FIGS. 3 and 4 are obtained for other angles of incidence on the filter pixels, for example, for angles of incidence of 0°, 20°, and 30°, respectively.

Thus, the provision of waveguides 114 in filter pixels Pix enables to increase the number of layers of a stack of dielectric layers above a photosensitive element 102, without increasing or while decreasing the crosstalk. In particular, when the layers are dielectric layers 110A of an interferometric filter 112, the increase in the number of layers 110A of the filter enables to improve its filtering characteristics (transmission in the passband, rejection outside of the passband, angular tolerance, etc.).

The guided propagation of light by waveguides 114 decreases the interaction of light with the layers 110A of filter 112 with respect to the case of a reference pixel comprising no waveguide 114. However, the increase in the number of layers 110A enables to increase the interaction between the evanescent portion of the guided modes and the layers 110A of filter 112, and thus to compensate for the loss of interaction between the light and filter 112 resulting from the guided propagation of light by waveguides 114.

According to an embodiment, it is desired to maximize the energy of the evanescent portion of the guided modes propagated by waveguides 114, to maximize the interaction of the guided modes with filter 112.

For example, for each pixel Pix, there is provided a step of determination of an arrangement of the waveguides 114 of pixel Pix with respect to one another, and of the dimensions of the cross-sections of the pixel waveguides 114 which maximizes an optical power of an evanescent portion of a super optical mode guided by the waveguides 114 of this pixel Pix. In other words, there is provided a step of determination of an arrangement of the waveguides 114 of pixel Pix with respect to one another, and of the dimensions of the cross-sections of the pixel waveguides 114 which maximizes a rejection rate of pixel Pix and/or a transmission rate of pixel Pix in a given range of angle of incidence of light on pixel Pix. At a given wavelength, the rate of transmission, respectively rejection, of a filter of pixel Pix, corresponds, for example, to the percentage of a light flux received by a first surface of pixel Pix, respectively which is not transmitted, to a second surface of pixel Pix, opposite to the first surface.

As an example, for each pixel Pix, for the evanescent portion of a mode guided by a waveguide 114 to sufficiently interact with the dielectric layers crossed by waveguide 114, waveguide 114 has a cross-section having its largest dimension dmax (length, side length, or diameter according to cases) equal, to within plus or minus 10%, to λmin/(2*Π*Dnmin), with λmin the smallest of the wavelengths of the spectral band of interest, and Dnmin the smallest optical index difference between the material of waveguide 114 and the dielectric materials of the layers crossed by waveguide 114.

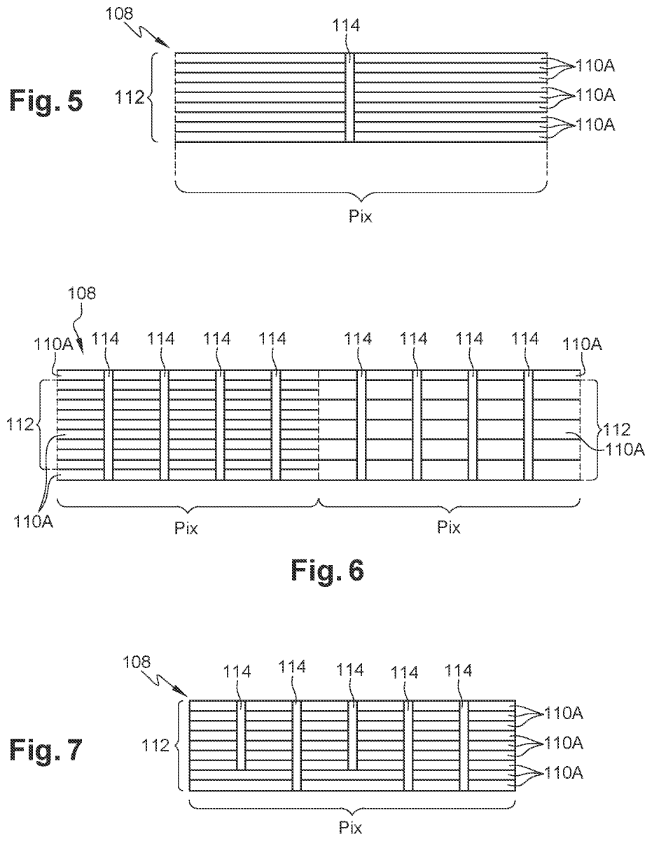

FIG. 5 is a simplified cross-section view of a pixel Pix of the pixelated filter 108 according to an alternative embodiment.

The pixel Pix of FIG. 5 differs from those of FIGS. 1 and 2 in that it does not comprise a plurality of waveguides 114, but only one waveguide 114. Preferably, this single waveguide 114 is aligned with the central axis of pixel Pix.

The single waveguide 114 of pixel Pix provides the same advantages as the plurality of waveguides 114 of a pixel Pix of FIGS. 1 and 2. However, as compared with a reference filter pixel comprising no waveguide, the increase of the transmission rate in the passband of the filter 112 of pixel Pix, the increase of the rejection rate outside of the passband of filter 112, and the crosstalk decrease are less significant in the case of the pixel Pix of FIG. 5 than in the case of a pixel Pix of FIGS. 1 and 2.

In the example of FIG. 5, waveguide 114 crosses all the layers 110A of pixel Pix. However, in other examples, not illustrated, waveguide 114 can only cross some of the layers 110A of pixel Pix.

In the example of FIG. 5, the filter 112 of pixel Pix comprises all the layers 110A of the stack of layers 110A of pixel Pix.

FIG. 6 is a simplified cross-section view of pixels Pix of pixelated filter 108 according to another alternative embodiment, two adjacent pixels Pix being illustrated in FIG. 6.

In this alternative embodiment, the two pixels Pix are different. More particularly, the two pixels Pix each have different filters 112.

For example, the pixel Pix arranged on the right-hand side in FIG. 6 comprises six layers 110A, and its filter 112 is formed of five of these six layers 110A, while the pixel Pix arranged on the left-hand side in FIG. 6 comprises thirteen layers 110A, and its filter 112 is formed of eleven of these thirteen layers 110A.

More generally, as illustrated by the example of FIG. 6, in each pixel Pix, the filter 112 of pixel Pix can only comprise part of the layers 110A of pixel Pix. For example, among the layers 110A of a pixel Pix, part of these layers 110A may form the filter 112 of pixel Pix, and another part of these layers 110A may be arranged on top of and/under the filter 112 of pixel Pix.

A pixel Pix may comprise layers 110A resting on its filter 112 and/or layers 110A having this filter 112 resting thereon, independently from the fact that this pixel Pix is different from its neighboring pixel.

In the example of FIG. 6, in each pixel Pix, waveguides 114 cross all the layers 110A of pixel Pix and, in particular, all the layers 110A of filter 112 of pixel pix. In other examples not illustrated, waveguides 114 may only cross part of the layers 110A of pixel Pix, for example only the layers 110A of the filter 112 of pixel Pix or only part of the layers 110A of filter 112.

The alternative embodiment illustrated in FIG. 6 in the case where each pixel Pix comprises a plurality of waveguides 114 applies to the case where at least one pixel Pix, for example, each pixel Pix, comprises a single waveguide 114.

FIG. 7 is a simplified cross-section view of a pixel Pix of the pixelated filter 108 of FIGS. 1 and 2 according to still another alternative embodiment. In the example of FIG. 7, all the layers 110A of pixel Pix belong to the filter 112 of pixel Pix.

In this variant, the waveguides 114 of pixel Pix have different lengths.

As an example, this alternative embodiment enables to apply a modification of the wave front of the light received by pixel Pix.

Although, in the example of FIG. 7, all the waveguides 114 of pixel Pix have their tops at the same level, in other examples, the waveguides 114 of pixel Pix may have tops at different levels.

Further, in another example not illustrated, all the waveguides 114 of a given pixel Pix have the same length which is different from that of one or a plurality of waveguides 114 of other pixels Pix of filter 108.

The alternative embodiment described in relation with FIG. 7 applies to the alternative embodiments of FIGS. 5 and 6.

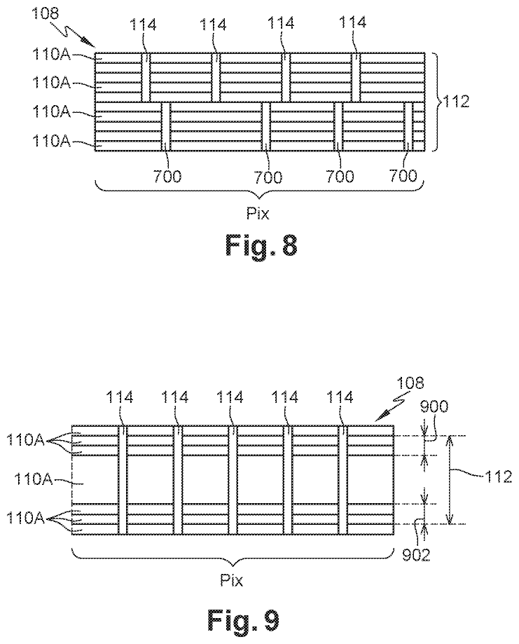

FIG. 8 is a simplified cross-section view of a pixel Pix of the pixelated filter 108 of FIGS. 1 and 2 according to still another alternative embodiment. In the example of FIG. 8, all the layers 110A of the filter of pixel Pix belong to the filter 112 of pixel Pix.

The pixel Pix of FIG. 8 differs from the pixels Pix of FIGS. 1 and 2 in that its waveguides 114 do not cross all the layers 110A of pixel Pix and that it comprises at least one waveguide 700 crossing other layers 110A of pixel Pix than those crossed by waveguides 114.

For example, in FIG. 8, pixel Pix comprises first layers 110A and second layers 110A, each waveguide 114 of the pixel Pix of FIG. 8 only crosses first layers 110A of pixel Pix and each waveguide 700 only crosses the second layers 110A of pixel Pix.

According to an embodiment, the layers 110A crossed by waveguides 700 all are dielectric layers. As an example, like for waveguides 114, waveguides 700 are then made of one or a plurality of materials, each having an optical index having its real part greater than the real part of the optical index of the material(s) of each second layer 110A crossed by waveguides 700.

As shown in FIG. 8, waveguides 114 may not be aligned with waveguides 700.

In the example of FIG. 8, waveguides 114 stop on the surface of a layer 110A from which waveguides 700 start.

In the example of FIG. 8, all the layers 110A of pixel Pix are crossed by a waveguide 114 or by a waveguide 700.

In another example, one or a plurality of layers 110A may be arranged between waveguides 114 and waveguides 700, that is, one or a plurality of layers 110 may be crossed by none of the waveguides 114 and 700 of pixel Pix.

In each pixel Pix, the number of waveguides 114 may be different from the number of waveguides 700, or be identical as illustrated in FIG. 8.

The provision of waveguides 700 in addition to waveguides 114 enables, for example, to simplify the manufacturing of pixel Pix, due to the fact that the trenches from which the waveguides, respectively 114 and 700, are formed, may be shallower than trenches from which waveguides 114 having a total length corresponding to the sum of the lengths of the waveguides 114 of the pixel Pix of FIG. 8 and of the length of the waveguides 700 of FIG. 8, would be formed.

The provision of waveguides 700 in addition to waveguides 114 enables, for example, to adapt the dimensions and the material(s) of waveguides 114, respectively 700, to the materials of the layers 110A crossed by waveguides 114, respectively 700, and to the wavelengths that these waveguides are configured to guide, in a finer and less complex fashion than in cases where the layers 110A crossed by waveguides 114 and 700 would only be crossed by longer waveguides 114.

The alternative embodiment described in relation with FIG. 8 applies to the alternative embodiments of FIGS. 5, 6, and 7.

FIG. 9 is a simplified cross-section view of a pixel Pix of the pixelated filter 108 of FIGS. 1 and 2 according to still another alternative embodiment. In the example of FIG. 9, pixel Pix comprises a filter 112 corresponding to a Fabry Perot cavity rather than to an interferometric filter.

As in the case of an interferometric filter 112, when interference filter 112 is a Fabry Perot cavity, filter 112 comprises a plurality of layers 110A of the stack of layers 110A of pixel Pix, for example, all the layers 110A of pixel Pix.

More particularly, filter 112 comprises a layer 110A sandwiched (or interposed) between a first semi-reflective layer 900 and a second semi-reflective layer 902.

According to an embodiment, each of layers 900 and 902 corresponds to a plurality of dielectric layers 110A of pixel Pix. In this case, waveguides 114 may cross layer 900 and/or layer 902, for example, the two layers 900 and 902 as illustrated in FIG. 9.

According to an alternative embodiment, each of layers 900 and 902 corresponds to one or a plurality of metal layers 110A. In this case, preferably, waveguides 114 do not cross layers 900 and 902, but only the layer 110A interposed between layers 900 and 902.

The alternative embodiments of FIGS. 5, 6, 7, and 8 apply to the case where the filter 112 of a pixel Pix is a Fabry Perot cavity rather than an interferometric filter.

More generally, pixelated filter 108 may comprise two pixels Pix different from each other due to the fact that these pixels Pix comprise different layers 110A and/or different waveguides 114 and/or different filters 112.

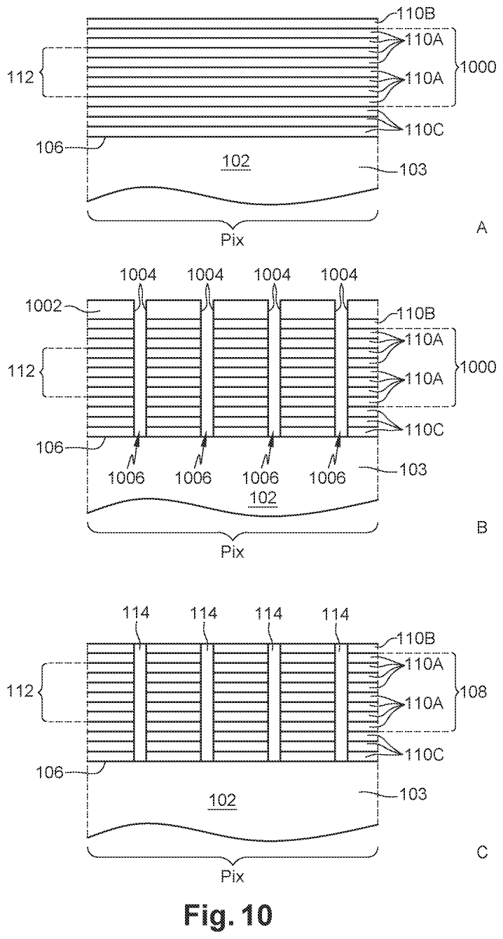

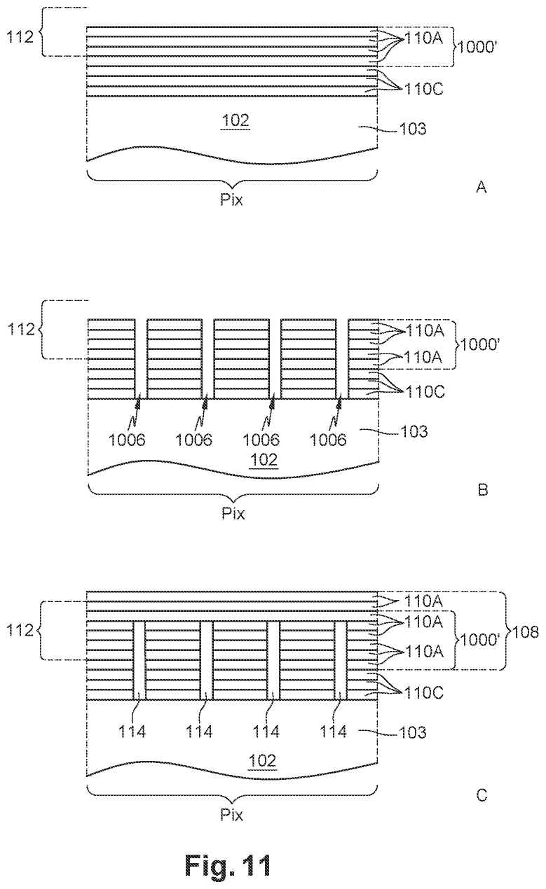

FIG. 10 illustrates, in cross-section views A, B, and C, an embodiment of a method of manufacturing a pixelated filter 108.

Although the manufacturing of a single pixel Pix of filter 108 is illustrated herein, those skilled in the art are capable of deducing therefrom how to manufacture filter 108, by implementing the steps described hereafter for each pixel Pix of filter 108, for example simultaneously for all or part of the pixels Pix of filter 108.

FIG. 10 illustrates the case where filter 108 is directly manufactured on a plurality 100 of photosensitive elements 102, for example on the surface 106 of a substrate 103 comprising photosensitive elements 102. In this case, each pixel Pix of filter 108 is manufactured in front of a corresponding element 102.

View A illustrates a structure 1000 comprising, at each location of a pixel Pix of filter 108, a stack of layers 110A.

In the embodiment of FIG. 10, at each location of pixel Pix, the stack of layers 110A of structure 1000 comprises all the layers 110A of the filter 112 of pixel Pix.

In the example of view A of FIG. 10, the stack of layers 110A of each stack of pixel Pix comprises all the layers 110A of pixel Pix.

In the example of view A of FIG. 10, one or a plurality of layers 110C are interposed between structure 1000 and the upper surface 106 of layer 103 comprising elements 102.

In the example of view A of FIG. 10, one or a plurality of layers 110B rest on structure 1000.

At the step of view B of FIG. 10, an etch mask 1002, preferably a hard mask, has been formed on structure 1000. In the example of FIG. 10, due to the fact that layers 110B rest on structure 1000, mask 1002 is formed on top of and in contact with a layer 110B. As an example, mask 1002 is made of SiO2, of SiN, of Al2O3, or of TiO2.

Still at the step of view B of FIG. 10, for each pixel Pix, one or a plurality of openings 1004 are formed through mask 1002. For example, an opening 1004 is formed at each location of a waveguide 114 of pixel Pix. Each opening 1004 has a shape, taken in a plane parallel to surface 106, which determines the shape of the cross-section of waveguide 114 which will be formed from this opening 1004.

Still at the step of view B of FIG. 10, for each pixel Pix, a trench 1006 is etched from each opening 1004. As an example, the implemented etch method enables to keep the dimensions of each opening 1004 along the entire length of the corresponding trench 1006, that is, the trench 1006 etched from this opening 1004.

The etching of trenches 1006 is such that, for each pixel Pix, each trench 1006 crosses at least some of the layers 110A of the filter 112 of pixel Pix. In the example of the view B of FIG. 10, trenches 1006 are etched through all the layers 110A of the filter 112 of each pixel Pix. More exactly, in the example of view B of FIG. 10, trenches 1006 are etched through all the layers 110A of structure 1000.

In the example of view B of FIG. 10, trenches 1006 are also etched through all the layers 110C.

At the step of view C of FIG. 10, the trenches 1006 of view B have been filled with the material(s) forming waveguides 114 to form, in each trench 1006, a corresponding waveguide 114.

As an example, the deposition of the material(s) forming waveguides 114 is performed by atomic layer deposition (ALD) or by plasma enhanced atomic layer deposition (PEALD).

Still at the step of view C of FIG. 10, a chemical-mechanical planarization or CMP has been performed at least all the way to layer 1002 to remove the excess material(s) of waveguide 114 which has been deposited on layer 1002 to fill trenches 1006.

As an example, the CMP is implemented to also remove the entire layer 1002. In another example, not illustrated, layer 1002 may be at least partially left in place, and then correspond to a layer 110B or 110A.

The implementation of the steps described hereabove enables to manufacture a pixelated filter 108 directly on photosensitive elements 102, each filter pixel Pix being manufactured in front of a corresponding element 102.

In the example of FIG. 10, at the step of view B, trenches 1006 cross all the layers 110A of filter 112. The waveguides 114 formed at the step of view C thus also cross all these layers 110A. Further, at the step of view B, trenches 1006 cross all the layers 110A of structure 1000, and the waveguides 114 formed at the step of view C thus cross all the layers 110A of structure 1000.

In another example not illustrated, trenches 1006 are only etched through part of the layers 110A of structure 1000, or even through only part of the layers 110A of filter 112. The waveguides 114 formed at the step of view B then only cross part of the layers 110A of filter 108, or even only part of the layers 110A of filter 112, that is, the layers 110A crossed by trenches 1006.

In the example of FIG. 10, at the step of view B, trenches 1006 cross all the layers 110C. The waveguides 114 formed at the step of view C thus cross all the layers 110C.

In another example not illustrated, at the step of view B, trenches 1006 only cross part of layers 110C. The waveguides 114 formed at the step of view C then only cross part of layers 110C, that is, those crossed by trenches 1006.

In still another example, not illustrated, layers 110C are omitted, structure 1000, and thus the filter 108 obtained at the step of view C, then resting on top of and in contact with photosensitive elements 102.

In the example of FIG. 10, at the step of view B, trenches 1006 cross layers 110B. The waveguides 114 formed at the step of view C thus cross these layers 110B.

In another example not illustrated, layers 110B are omitted at the step of view A.

Further, although this is not illustrated in FIG. 10, an optional additional step of forming of one or a plurality of additional layers 110B may be provided after the forming of waveguides 114. Waveguides 114 thus do not cross these additional layers 110B formed after waveguides 114.

FIG. 11 illustrates, in cross-section views A, B, and C, an alternative embodiment of the manufacturing method of FIG. 10.

Although the manufacturing of a single pixel Pix of filter 108 is illustrated herein, those skilled in the art are capable of deducing therefrom how to manufacture filter 108, by implementing the steps described hereafter for each pixel Pix of filter 108, for example simultaneously for all or part of the pixels Pix of filter 108.

FIG. 11 illustrates the case where filter 108 is directly manufactured on a plurality of photosensitive elements 102, for example, on the surface 106 of a substrate 103 comprising the plurality of photosensitive elements. In this case, each pixel Pix of filter 108 is manufactured in front of a corresponding element 102.

View A illustrates a structure 1000′ comprising, at each location of a pixel Pix of filter 108, a stack of layers 110A.

In the alternative implementation of FIG. 11, at each location of pixel Pix, the stack of layers 110A of structure 1000′ only comprises part of the layers 110A of pixel Pix, for example, only part of the layers 110A of the filter 112 of pixel Pix.

In the example of view A of FIG. 11, one or a plurality of layers 110C are interposed between structure 1000′ and the upper surface 106 of elements 102.

At the step of view B of FIG. 11, similar to that of view B of FIG. 10, an etch mask 1002 (not shown in FIG. 11) has been formed on structure 1000′ and, for each pixel Pix, one or a plurality of openings 1004 (not shown in FIG. 11) have been formed through mask 1002 and then a trench 1006 has been etched from each opening 1004.

In the example of view B of FIG. 11, trenches 1006 are etched through all the layers 110A of structure 1000′.

In the example of view B of FIG. 11, trenches 1006 are also etched through all the layers 110C.

At the step of view C of FIG. 11, similar to the step of view C of FIG. 10, waveguides 114 are formed by filling trenches 1006 and a CMP is performed to remove all or part of mask 1002, for example to totally remove mask 1002 in the example of FIG. 11.

Further, still at the step of view C of FIG. 11, after the forming of waveguides 114, the layer(s) 110A of filter 108 which did not form part of structure 1000′, that is, which were absent at the step of view A of FIG. 11, have been formed on structure 1000′ provided with waveguides 114. Thus, in this variant, the waveguides do not cross all the layers 110A of each pixel Pix, for example do not cross all the layers 110A of the filter 112 of pixel Pix.

Like for the method of FIG. 10, although this is not illustrated in FIG. 11, an additional optional step of forming of one or a plurality of layers 110B may be provided after the deposition of the layers 110A of view C of FIG. 11.

The implementation of the steps described hereabove enables to manufacture a pixelated filter 108 directly on photosensitive elements 102, each filter pixel Pix being manufactured in front of a corresponding element 102.

In the example of FIG. 11, at the step of view B, trenches 1006 cross all the layers 110C. In another example not illustrated, at the step of view B, trenches 1006 only cross part of layers 110C. In still another example, layers 110C are omitted, structure 1000′, and thus the filter 108 obtained at the step of view C, then resting on top of and in contact with photosensitive elements 102.

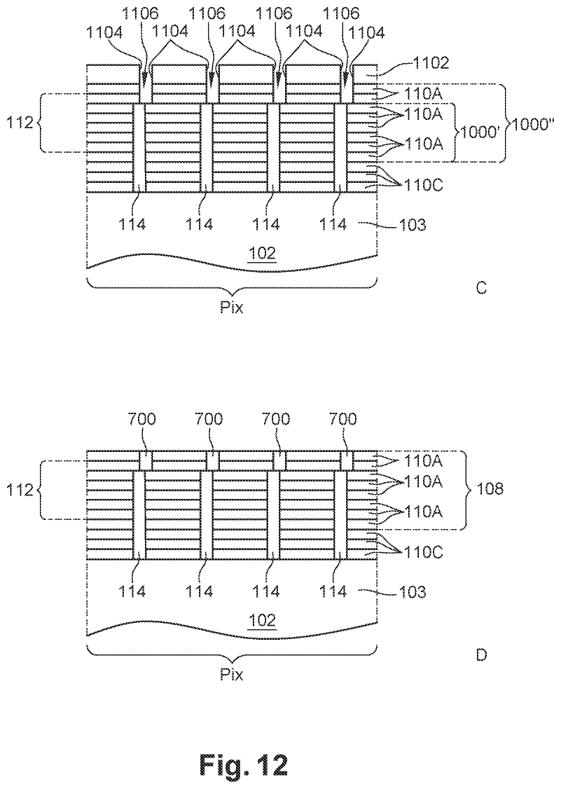

FIG. 12 illustrates, in cross-section views C and D, an alternative embodiment of the manufacturing method of FIG. 11.

View C illustrates a step of the method following the step of view B of FIG. 11, in the case where the forming of layers 110A after the forming of waveguides 114 leads to obtaining an intermediate structure 1000″. At this step, a mask 1102, similar or identical to mask 1002, has been formed on structure 1000″. Although this is not the case in FIG. 12, before the forming of mask 1102, one or a plurality of layers 110B may be formed, similarly to what is shown by view A of FIG. 10 where layers 110B rest on structure 1000 and under mask 1002.

Still at the step of view C of FIG. 12, similarly to what has been described in relation with view B of FIG. 10 and with view B of FIG. 11, trenches 1106 have been etched from each opening 1104. Preferably, the etching of these trenches is stopped before the first layer 110A crossed by waveguides 114.

At the step of view D of FIG. 12, waveguides 700 have been formed in trenches 1104, similarly to the way in which waveguides 114 have been formed in trenches 1004. Like for waveguides 114, a CMP is implemented after the filling of trenches 1104 to remove the excess material of waveguides 700 which rests on mask 1102, and, optionally, all or part of mask 1102.

Optionally, one or a plurality of layers 110B may be formed after the forming of waveguides 700, for example, after the CMP step.

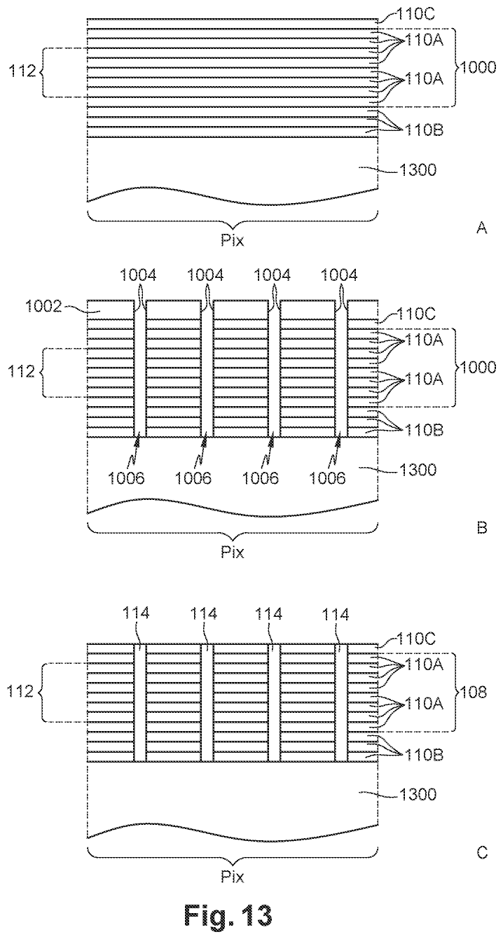

FIG. 13 illustrates, in cross-section views A, B, and C, another implementation mode of a method of manufacturing a pixelated filter 108. Although the manufacturing of a single pixel Pix of filter 108 is illustrated herein, those skilled in the art are capable of deducing therefrom how to manufacture filter 108, by implementing the steps described hereafter for each pixel Pix of filter 108, for example, simultaneously for all or part of the pixels Pix of filter 108.

FIG. 13 illustrates the case where filter 108 is manufactured on a support 1300, rather than directly on a layer 103 comprising photosensitive elements 102. In this case, the manufactured filter 108 is configured to rest on a surface 106 of photosensitive elements 102 so that, when filter 108 effectively rests on elements 102, each element 102 is in front of a pixel Pix of pixelated filter 108.

Views A, B, and C of FIG. 13 differ from the respective views A, B, and C of FIG. 10 in that:
the layer 103 comprising elements 102 is replaced with a support 1300; and
the position of layers 110B and 100C is interchanged, that is, the layers arranged between support 1300 and structure 1000 are here referenced as 110B rather than 110C as was the case in FIG. 10, and that the layers resting on structure 1000 are here referenced as 110C rather 110B as was the case in FIG. 10.

For the rest, the description made of views A, B, and C of FIG. 10 applies to the respective views A, B, and C of FIG. 13, by interchanging references 110B and 110C in this description. In particular, the different examples of implementation described in relation with FIG. 10 apply to the method of FIG. 13, by interchanging references 110B and 110C in the description made of these examples in relation with FIG. 10.

More generally, the examples of alternative embodiments described in relation with FIGS. 11 and 12 apply to the case where layers 110B and 110C are interchanged and where the plurality of elements 102 is replaced with a support 1300, by interchanging references 110B and 110C in the previously made description of these examples.

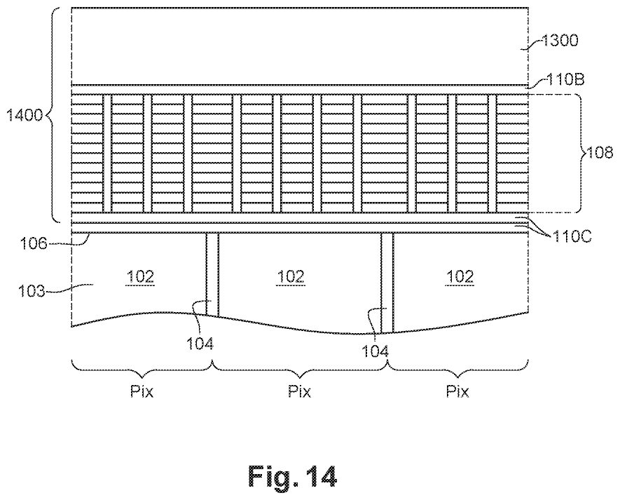

FIG. 14 illustrates in a cross-section view a next step of a method of manufacturing filter 108 on support 1300. In FIG. 14, call 1400 the assembly of support 1300 and of filter 108 obtained at the end of one of the previously-described examples of manufacturing method.

In this example, a layer 110B is interposed between support 1300 and filter 108. In other example, not illustrated, a plurality of layers 110B is provided between support 1300 and filter 108, or filter 108 may be directly in contact with support 1300. In other words, according to the considered example, assembly 1400 may or not comprise one or a plurality of layers 110B.

As an example, in FIG. 14, layer 110B is an etch stop layer for the etching of trenches 1006 (see FIG. 13).

In this example, a layer 110C has been formed on filter 108, on the side opposite to support 1300. In other examples not illustrated, a plurality of layers 110B may be formed on filter 108 or, conversely, no layer 110C is formed on filter 108. In other words, according to the considered example, assembly 1400 may or not comprise one or a plurality of layers 110C.

As an example, in FIG. 14 layer 110C is a passivation layer.

At the step of FIG. 14, the assembly 1400 comprising support 1300 and filter 108 has been transferred onto a plurality of elements 102, that is, onto a surface 106 of a layer 103 comprising elements 102, so that each element 102 is located in front of a pixel Pix of filter 108.

As an example, before the transfer step, a passivation layer 110C has been formed on the surface 106 of elements 102, so that its placing into contact with the passivation layer 110C of assembly 1400 allows a molecular bonding.

Support 1300 may then be thinned, or even removed. Of course, in the case where all or part of support 1300 is left in place on filter 108 after its transfer onto elements 102, support 1300 is made of a material transparent to the wavelengths transmitted by pixels Pix.

Those skilled in the art are capable of adapting the examples of method implementation modes described hereabove in relation with FIGS. 10 to 14 to the case of a pixel Pix comprising a single waveguide 114.

Further, in the previously-described examples of method implementation modes, trenches 1006 all have the same length, whereby the waveguides 114 which are formed therein all have the same length. Those skilled in the art are capable of adapting these examples to the case where waveguides 114 have different wavelengths, for example by repeating the steps of masking, trench etching, filling of the trenches to form waveguides therein for each different length of waveguide 114.

Examples of embodiments and of variants have been described hereabove in cases where device 1 is a light sensor and where photoactive elements 102 are photosensitive elements configured to receive light. Those skilled in the art are capable of adapting these examples of embodiments and of variants to the case where device 1 is a light-emitting device, for example, a micro-display, elements 102 then being light-emitting elements configured to emit light.

Further, although this is not claimed by the present application, those skilled in the art are capable of adapting all the described examples of embodiment to cases where waveguides 114 cross all or part of the layers of a stack of layers, preferably dielectric, resting on top of and in front of a photoactive element 102, when this stack of layers comprises no interference filter, the guides then enabling to decrease the crosstalk between pixels Pix.

Various embodiments and variants have been described. Those skilled in the art will understand that certain features of these various embodiments and variants may be combined, and other variants will occur to those skilled in the art. In particular, although filter pixels Pix, each comprising a single interference voltage 112, have been shown, those skilled in the art are capable, based on the description made hereabove, to provide for one or a plurality of pixels Pix to comprise a plurality of interference filters.

Finally, the practical implementation of the described embodiments and variations is within the abilities of those skilled in the art based on the functional indications given hereabove. In particular, those skilled in the art are capable of determining, for each pixel and according to the targeted application:
the dimensions, the number, and the materials of waveguides 114;
the number, the materials, and the thicknesses of the layers 110A of each filter 112; and
the arrangement or the distribution of waveguides 114. For this purpose, those skilled in the art may, for example, use results of simulations, for example, simulations using the FDTD calculation, for example, simulations implemented by means of the software designated with trade name Lumerical.

1. Pixelated filter wherein:
each pixel of the pixelated filter comprises an interference filter comprising a stack of layers, and a plurality of waveguides, each crossing all or part of the layers of said interference filter; and
in each pixel of the pixelated filter, the waveguides are configured to guide at least one optical mode and so that an evanescent portion of said at least one guided mode is filtered by the interference filter of said pixel.

2. Pixelated filter according to claim 1, wherein the waveguides of each two neighboring pixels of the pixelated filter are configured so that the guided optical modes of the two pixels do not couple with one another.

3. Pixelated filter according to claim 1, configured to rest on a surface of a plurality of photoactive elements so that each photoactive element is in front of a pixel of the pixelated filter.

4. Pixelated filter according to claim 1, wherein at least two pixels of the pixelated filter are different.

5. Pixelated filter according to claim 1, wherein, in each pixel of the pixelated filter, the layers crossed by the waveguides are dielectric layers, and each waveguide is made of one or a plurality of materials each having a refraction index having its real part greater than the real part of the refraction index of each of the dielectric layers crossed by said waveguide.

6. Pixelated filter according to claim 1, wherein each waveguide has a substantially constant cross-section along its entire length.

7. Pixelated filter according to claim 1, wherein the waveguides of one or a plurality of pixels of the pixelated filter have different lengths.

8. Pixelated filter according to claim 1, wherein, in each pixel of the pixelated filter, the waveguides of said pixel are made of the same material and have a same cross-section.

9. Pixelated filter according to claim 1, wherein in each pixel of the pixelated filter, the waveguides of said pixel are organized in a network.

10. Pixelated filter according to claim 9, wherein, in at least one of the pixels of the pixelated filter, the network of waveguides of said pixel is symmetrical with respect to a central axis of said pixel and the waveguides of the network each have a same cross-section, symmetrical with respect to a central longitudinal axis of said waveguide.

11. Device comprising:
a plurality of photoactive elements; and
a pixelated filter according to claim 1, wherein the pixelated filter rests on the plurality of photoactive elements so that each photoactive element is in front of a pixel of the pixelated filter.

12. A manufacturing method of a pixelated filter according to claim 1, comprising the following steps:
a) providing a structure comprising, at each location of a pixel of the pixelated filter, a stack of all or part of the layers of an interference filter of said pixel;
b) for each pixel of the pixelated filter, forming a mask and a plurality of openings in said mask;
c) for each pixel of the pixelated filter, etching a trench from each opening, the trench crossing all or part of the layers of the interference filter of said pixel; and
d) filling each trench to form a waveguide therein,
wherein, in each pixel of the pixelated filter, the waveguides are configured to guide at least one optical mode and so that an evanescent portion of said at least one guided mode is filtered by the interference filter of said pixel.

13. Method according to claim 12, wherein, at step a), for each pixel, the stack comprises only part of the layers of the interference filter of said pixel, the method comprising after step d), for each pixel, the forming of the other part of the layers of the interference filter of said pixel.

14. Method of manufacturing a device comprising:
manufacturing, on a support, a pixelated filter by implementing the method according to claim 12;
transferring the pixelated filter and the support onto a plurality of photoactive elements so that each photoactive element is in front of a pixel of the pixelated filter and that the pixelated filter is interposed between the plurality of photoactive elements and the support.

15. Method according to claim 14, further comprising, after the transfer step:
a step of thinning of said support, said support being made of a material transparent to the wavelengths transmitted by each of the interference filters; or
a step of removal of said support.

16. Device manufacturing method comprising the manufacturing, on a plurality of photoactive elements, of a pixelated filter by implementing the method according to claim 1, so that each photoactive element is in front of a pixel of the pixelated filter.

17. Method according to claim 12, further comprising, for each pixel of the pixelated filter, a step of determination of an arrangement of the waveguides of said pixel with respect to one another and of the dimensions of the cross-sections of said waveguides of said pixel maximizing an optical power of an evanescent portion of a super optical mode guided by the waveguides of said pixel.
